(19) United States
(12) Patent Application Publication
(10) Pub. No.: US 2025/0357102 A1
(43) Pub. Date: Nov. 20, 2025

(54) SUBSTRATE TREATMENT METHOD

(71) Applicant: Tokyo Electron Limited, Tokyo (JP)

(72) Inventors: Miyako KANEKO, Yamanashi (JP); Tadashi MITSUNARI, Yamanashi (JP)

(21) Appl. No.: 19/285,270

(22) Filed: Jul. 30, 2025

Related U.S. Application Data
(63) Continuation of application No. PCT/JP2024/007439, filed on Feb. 28, 2024.

(30) Foreign Application Priority Data
Mar. 7, 2023 (JP) 2023-034413

(51) Int. Cl. H01L 21/02; H10N 50/01

(52) U.S. Cl. CPC H01L 21/02115; H01L 21/02252; H01L 21/02312; H10N 50/01

(57) ABSTRACT

A substrate treatment method includes a) exposing a substrate to a first surface treatment agent, thereby pre-treating a substrate surface of the substrate; b) exposing the substrate treated in a) to a second surface treatment agent, thereby hydrophobizing the substrate surface; and c) exposing the substrate treated in b) to a plasma of a processing gas containing a carbon-containing gas, thereby forming a carbon-containing film having a film stress of 1 GPa or more over the hydrophobized substrate surface.

### CROSS-REFERENCE TO RELATED APPLICATIONS

This application is a continuation application of International Application No. PCT/JP2024/007439, filed on Feb. 28, 2024, and designated the U.S., which is based upon and claims priority to Japanese Patent Application No. 2023-034413, filed on Mar. 7, 2023, the entire contents of which are incorporated herein by reference.

### BACKGROUND

### 1. Field of the Invention

The present disclosure relates to a substrate treatment method.

### 2. Description of the Related Art

Japanese Laid-Open Patent Application Publication No. 2020-191427 discloses a substrate treatment method for forming a carbon film as a hard mask.

### SUMMARY

According to an aspect of the present disclosure, a substrate treatment method includes a) a first step of exposing a substrate to a first surface treatment agent, thereby pre-treating a substrate surface of the substrate; b) a second step of exposing the substrate treated in a) to a second surface treatment agent, thereby hydrophobizing the substrate surface; and c) a third step of exposing the substrate treated in b) to a plasma of a processing gas containing a carbon-containing gas, thereby forming a carbon-containing film having a film stress of 1 GPa or more over the hydrophobized substrate surface.

### BRIEF DESCRIPTION OF THE DRAWINGS

FIG. 1 is a flowchart illustrating an example of a substrate treatment method of the present disclosure.

FIG. 2 is an example of a schematic cross-sectional view of a substrate W treated by the substrate treatment method.

FIG. 3A is an example of a schematic diagram illustrating a surface state of the substrate W.

FIG. 3B is an example of a schematic diagram illustrating the surface state of the substrate W.

FIG. 3C is an example of a schematic diagram illustrating the surface state of the substrate W.

FIG. 3D is an example of a schematic diagram illustrating the surface state of the substrate W.

FIG. 4 is an example of an apparatus configured to perform a pre-treatment step on the substrate W.

FIG. 5 is another example of the apparatus configured to perform the pre-treatment step on the substrate W.

FIG. 6 is an example of an apparatus configured to perform a hydrophobization step on the substrate W.

FIG. 7 is a schematic cross-sectional view illustrating an example of a plasma processing apparatus.

FIG. 8 is a diagram illustrating a state of a carbon-containing film formed over a substrate surface.

FIG. 9 is a diagram illustrating a relationship between various pre-treatments and adhesiveness of a DLC (diamond-like carbon) film.

### DETAILED DESCRIPTION OF THE DISCLOSURE

In one aspect, the present disclosure provides a substrate treatment method in which film delamination is suppressed.

Hereinafter, embodiments of the present disclosure will be described with reference to the drawings. In the drawings, the same components are denoted by the same reference symbols, and thus duplicate description thereof may be omitted.

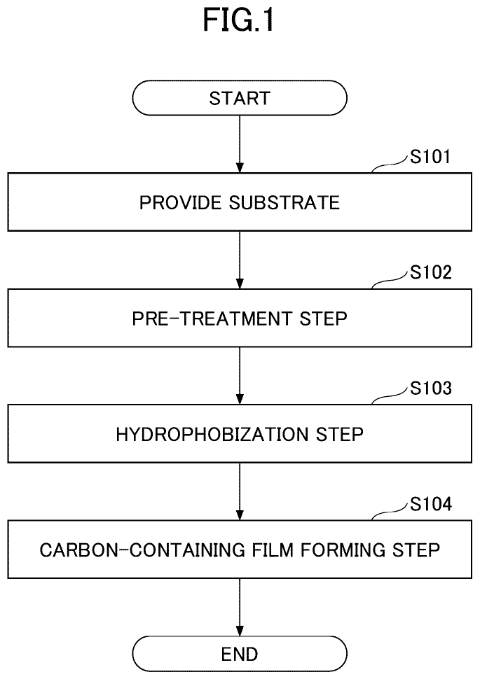

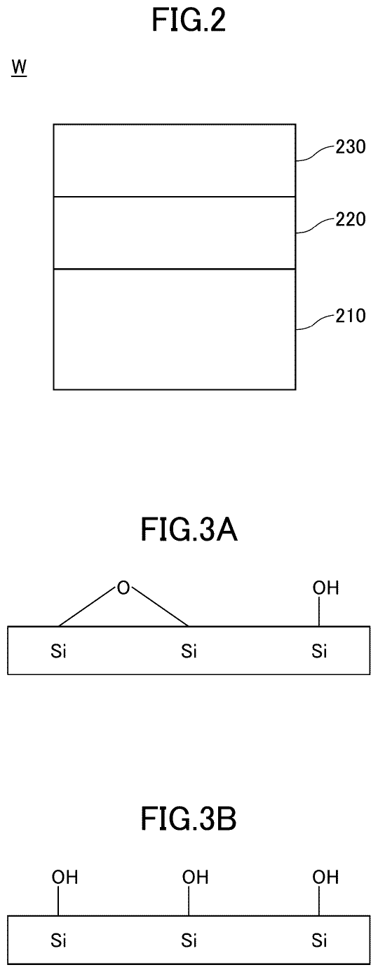

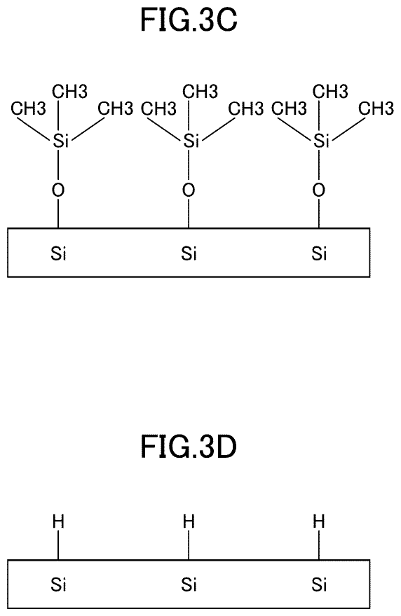

FIG. 1 is a flowchart illustrating an example of the substrate treatment method. FIG. 2 is an example of a schematic cross-sectional view of a substrate W treated by the substrate treatment method. FIGS. 3A to 3D are examples of schematic diagrams illustrating a surface state of the substrate W.

Here, as illustrated in FIG. 2, a carbon-containing film 230 is formed over the substrate W including a first layer 210 and a second layer 220 that are stacked. The first layer 210 is, for example, an MTJ (magnetic tunnel junction) element. The second layer 220 may be, for example, an Si-containing film (e.g., Si or SiN). Alternatively, the second layer 220 may be, for example, TiN.

Before a step of forming the carbon-containing film 230, a step of forming the second layer 220 over the substrate W including the first layer 210 (a fourth step) may be included. The step of forming the second layer 220 may be a step of supplying an Si-containing gas and a reactive gas (e.g., a hydrogen gas or a nitrogen-containing gas) to the substrate W, thereby forming an Si-containing film over the substrate W (over the first layer 210). The step of forming the second layer 220 may be a step of supplying a titanium-containing gas and a nitrogen-containing gas to the substrate W, thereby forming a TiN film over the substrate W (over the first layer 210).

The carbon-containing film 230 is, for example, a DLC (diamond-like carbon) film. When the second layer 220 is TiN, the second layer 220 and the carbon-containing film 230 can be used as a hard mask for the first layer 210 (e.g., an MTJ element). In this case, the thickness of the TiN film (the second layer 220) is preferably 20 nm or more and 100 nm or less. The thickness of the DLC film (the carbon-containing film 230) is preferably 20 nm or more and 100 nm or less.

Here, the DLC film has a high compressive stress. Therefore, film delamination can occur in the carbon-containing film 230 formed over the second layer 220. Against this, the substrate treatment method illustrated in FIG. 1 suppresses film delamination in the carbon-containing film 230.

In step S101, the substrate W is provided. Here, the substrate W to be provided includes the first layer 210 and the second layer 220 (see FIG. 2). A substrate surface of the provided substrate W is a surface of the second layer 220, and is, for example, Si, SiN, or TiN.

FIG. 3A is an example of a surface state of the substrate W provided in step S101. Here, for example, the second layer 220 is an Si-containing film. In some portions of the second layer 220 (see the left side of FIG. 3A), silicon (Si) in the second layer 220 forms Si—O—Si as a result of dehydration between one silanol group and another silanol group next to the one silanol group. Also, in other portions of the second layer 220 (see the right side of FIG. 3A), silicon (Si) in the second layer 220 forms Si—OH.

In step S102, the substrate W is exposed to a first surface treatment agent, thereby pre-treating the substrate surface (a pre-treatment step, or a first step). This step forms, at the substrate surface, a functional group that is to be physically adsorbed onto and/or chemically bonded to a second surface treatment agent described below (see step S103). Specifically, a hydrophilic OH group is formed at the substrate surface.

When Si is contained in the substrate surface (e.g., Si or SiN), the first surface treatment agent contains at least one of oxidant solutions, such as an ammonia-hydrogen peroxide mixture (a mixture of ammonia and hydrogen peroxide), H₂O₂, a hydrochloric acid-hydrogen peroxide mixture (a mixture of hydrochloric acid and hydrogen peroxide), ozone (O₃) water, a sulfuric acid-hydrogen peroxide mixture, an ammonium peroxodisulfate aqueous solution, and the like. Preferably, the first surface treatment agent contains ammonia, hydrogen peroxide, and pure water, and a ratio of ammonia, hydrogen peroxide, and pure water is greater than or equal to 1:1:20 and less than or equal to 1:1:100. The temperature of the first surface treatment agent is preferably 40° C. or higher and 60° C. or lower.

When an ammonia-hydrogen peroxide mixture, H₂O₂, or the like is used as the first surface treatment agent, particles, organic substances, and the like adhering to the substrate surface are removed. This enhances reactivity between the substrate surface and the second surface treatment agent described below.

FIG. 3B is an example of the surface state of the substrate W that is pre-treated in step S102. By exposing the substrate W to the first surface treatment agent for pre-treating the substrate surface, the substrate surface is changed from a state in which Si—O—Si and Si—OH coexist (see FIG. 3A) to a state in which Si—OH is abundant. The pre-treatment in step S102 changes the substrate surface to a hydrophilic surface. In other words, the pre-treatment in step S102 changes the substrate surface to be in a state in which hydrophilic OH groups are abundant.

When the substrate surface is TiN, the first surface treatment agent contains at least one of pure water, water vapor for exposure, a dilute and room-temperature ammonia-hydrogen peroxide mixture, a dilute and room-temperature hydrochloric acid-hydrogen peroxide mixture, or dilute ozone water.

The pre-treatment step includes a step of oxidizing the substrate surface and a step of treating the substrate surface with pure water. The step of oxidizing the substrate surface changes TiN at the substrate surface to TiO₂, for example, by exposing the substrate surface to an O₂ gas atmosphere, exposing the substrate surface to an O₃ gas atmosphere, or heating the substrate W in an open-air atmosphere. The step of treating the substrate surface with pure water changes TiO₂ at the substrate surface to TiOH by exposing the substrate surface to pure water. The pre-treatment in step S102 changes the substrate surface to a hydrophilic surface. In other words, the pre-treatment in step S102 changes the substrate surface to be in a state in which hydrophilic OH groups are abundant.

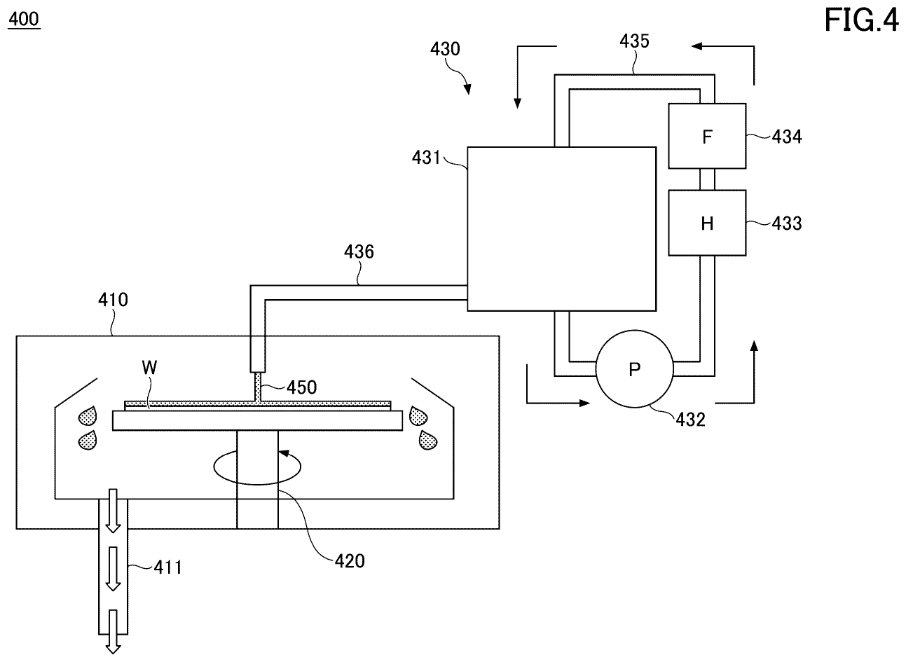

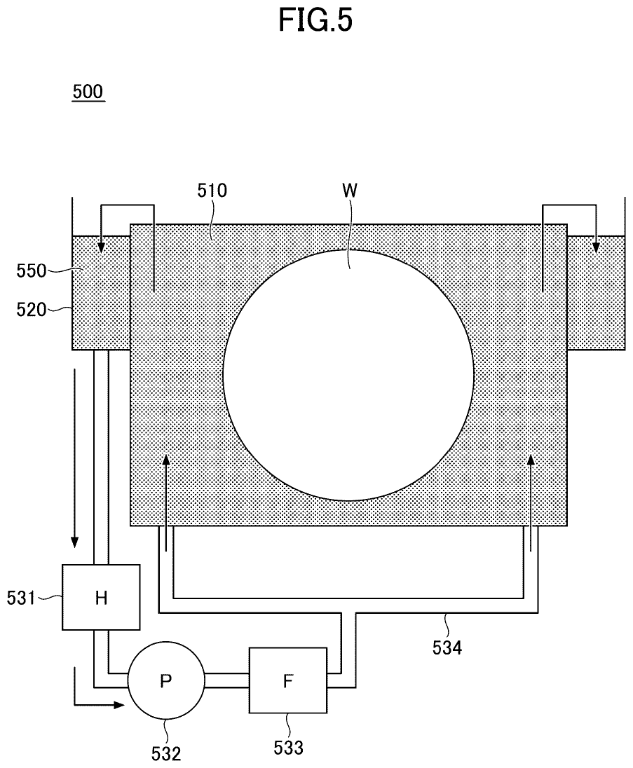

Here, an example of an apparatus configured to supply the first surface treatment agent in the form of liquid to the substrate surface will be described with reference to FIGS. 4 and 5.

FIG. 4 is an example of an apparatus configured to perform the pre-treatment step on the substrate W. The apparatus configured to perform the pre-treatment step on the substrate W may be a single-wafer cleaning apparatus 400 as illustrated in FIG. 4. The cleaning apparatus 400 includes a treatment chamber 410, a stage 420 that is rotatable with the substrate W being placed on the stage 420, and a chemical solution supply 430.

The chemical solution supply 430 includes a chemical solution tank 431, a pump 432, a heater 433, a filter 434, a circulation path 435, and a supply path 436. The circulation path 435 is formed to pass through the chemical solution tank 431, the pump 432, the heater 433, and the filter 434. Arrows indicate a circulation direction of the chemical solution. By circulating the chemical solution, a chemical solution 450 (the first surface treatment agent) in the chemical solution tank 431 is heated to a predetermined temperature. The chemical solution 450 in the chemical solution tank 431 is supplied to the substrate surface of the treatment chamber 410 through the supply path 436. As the stage 420 rotates, the chemical solution 450 flows toward the outer periphery of the substrate W, and is discharged through a discharge path 411. Also, the supply of the chemical solution from the chemical solution supply 430 to the treatment chamber 410 is stopped, and the stage 420 on which the substrate W is placed is rotated, thereby drying the substrate W.

FIG. 5 is another example of the apparatus configured to perform the pre-treatment step on the substrate W. The apparatus configured to perform the pre-treatment step on the substrate W may be a batch-type cleaning apparatus 500 as illustrated in FIG. 5. The cleaning apparatus 500 includes an inner tank 510 in which the substrate W is housed, an outer tank 520, a heater 531, a pump 532, a filter 533, and a flow path 534.

The inner tank 510 and the outer tank 520 store a chemical solution 550 (the first surface treatment agent). The chemical solution 550 discharged from the inner tank 510 flows into the outer tank 520. The chemical solution 550 in the outer tank 520 passes through the heater 433, the pump 432, and the filter 434 through the flow path 534, is heated to a predetermined temperature, and is supplied to the inner tank 510. Arrows indicate a circulation direction of the chemical solution.

In step S103 illustrated in FIG. 1, the substrate W is exposed to the second surface treatment agent, thereby hydrophobizing the substrate surface (a hydrophobization step, or a second step). Here, the second surface treatment agent is physically adsorbed onto and/or chemically bonded to the OH groups at the substrate surface formed in step S102. Alternatively, the second surface treatment agent is chemically reacted with the OH groups at the substrate surface formed in step S102.

When Si is contained in the substrate surface (e.g., Si or SiN), the second surface treatment agent contains at least one of DHF (dilute HF), HMDS (hexamethyldisilazane), TMSDMA (trimethylsilyldimethylamine), or a silane coupling agent. Preferably, the second surface treatment agent contains HF and pure water, and a ratio of HF and pure water is greater than or equal to 1:50 and less than or equal to 1:200. The temperature of the second surface treatment agent is preferably 20° C. or higher and 30° C. or lower. The temperature of the other second surface treatment agents is preferably 60° C. or higher and 150° C. or lower.

FIG. 3C is an example of the surface state of the substrate W that is hydrophobized in step S103. Here, HMDS is used as the second surface treatment agent. As illustrated in FIG. 3C, the second surface treatment agent is physically adsorbed onto and/or chemically bonded to the hydrophilic OH groups (see FIG. 3B) at the substrate surface. Here, Si—O—Si (CH₃)₃ is formed at the substrate surface. The hydrophobizing treatment illustrated in step S103 changes the substrate surface to a hydrophobic surface.

FIG. 3D is an example of the surface state of the substrate W that is hydrophobized in step S103. Here, DHF is used as the second surface treatment agent. As illustrated in FIG. 3D, the second surface treatment agent is chemically reacted with the hydrophilic OH groups (see FIG. 3B) at the substrate surface. Here, Si—H is formed at the substrate surface through chemical reaction. The hydrophobizing treatment illustrated in step S103 changes the substrate surface to a hydrophobic surface.

When the substrate surface is TiN, the second surface treatment agent contains at least one of HMDS (hexamethyldisilazane), IPA (isopropyl alcohol), TMSDMA (trimethylsilyldimethylamine), cetyl alcohol, or a silane coupling agent. The temperature of the second surface treatment agent is preferably 60° C. or higher and 150° C. or lower.

Similar to the case in which the substrate surface is TiN, the second surface treatment agent is physically adsorbed onto and/or chemically bonded to the hydrophilic OH groups at the substrate surface through the hydrophobizing treatment illustrated in step S103. Alternatively, the second surface treatment agent is chemically reacted with the OH groups at the substrate surface through the hydrophobizing treatment illustrated in step S103. The hydrophobizing treatment illustrated in step S103 changes the substrate surface to a hydrophobic surface.

Here, the cleaning apparatus 400 illustrated in FIG. 4 and the cleaning apparatus 500 illustrated in FIG. 5 may be used as the apparatus configured to supply the second surface treatment agent in the form of liquid to the substrate surface.

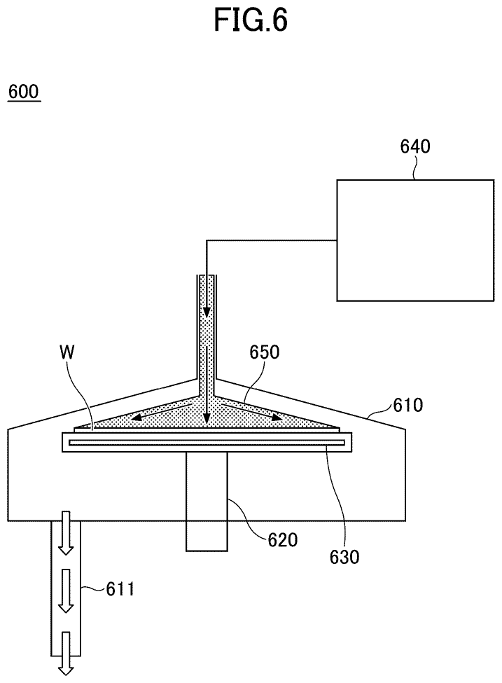

An example of the apparatus configured to supply the second surface treatment agent in the form of gas to the substrate surface will be described with reference to FIG. 6.

FIG. 6 is an example of an apparatus configured to perform the hydrophobization step on the substrate W. The apparatus configured to perform the hydrophobization step on the substrate W may be a gas treatment apparatus 600 illustrated in FIG. 6. The gas treatment apparatus 600 includes a treatment chamber 610, a stage 620 on which the substrate W is to be placed, a heater 630 provided in the stage 620 and configured to heat the stage 620 and the substrate W, and a gas supply 640. The gas supply 640 includes a vaporizer, and vaporizes a chemical solution (the second surface treatment agent). A vaporized chemical solution 650 is supplied to the treatment chamber 610. The vaporized chemical solution 650 after the treatment is discharged through a discharge path 611.

In step S104, the substrate W is exposed to a plasma of a processing gas containing a carbon-containing gas, thereby forming the carbon-containing film 230 having a film stress of 1 GPa or more over the hydrophobized substrate surface (a carbon-containing film forming step, or a third step). The film stress may be in a compression direction or in a tensile direction. That is, the carbon-containing film 230 having a film stress of 1 GPa or more as an absolute value is formed.

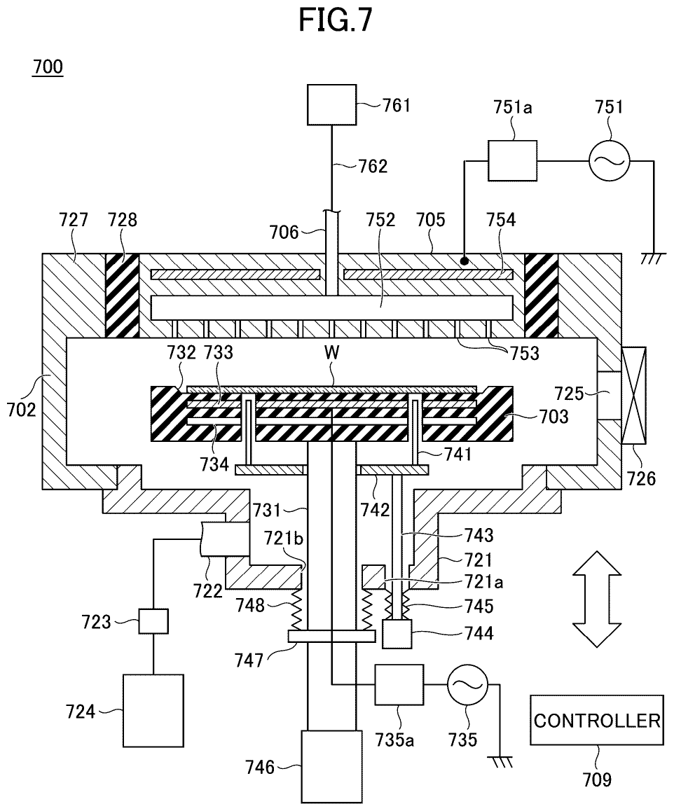

Here, an example of an apparatus configured to form the carbon-containing film 230 will be described with reference to FIG. 7. FIG. 7 is a schematic cross-sectional view illustrating an example of a plasma processing apparatus 700. The plasma processing apparatus 700 is an apparatus configured to form a carbon-containing film (e.g., a DLC film) over the substrate W through CVD (chemical vapor deposition) in a processing chamber 702 under reduced pressure.

The plasma processing apparatus 700 includes the processing chamber 702 that is substantially cylindrical and airtight. A gas exhaust chamber 721 is provided at the center of the bottom wall of the processing chamber 702. The gas exhaust chamber 721 has, for example, a substantially cylindrical shape projecting downward. A gas exhaust path 722 is connected to the gas exhaust chamber 721, for example, at the side surface of the gas exhaust chamber 721. A gas exhauster 724 is connected to the gas exhaust path 722 through a pressure adjuster 723. The pressure adjuster 723 includes a pressure adjusting valve, such as a butterfly valve or the like. The gas exhauster 724 connected to the gas exhaust path 722 is configured to reduce the internal pressure of the processing chamber 702. A transfer port 725 is provided in the side surface of the processing chamber 702. The transfer port 725 is configured to be openable or closable by a gate valve 726. Transfer of the substrate W between the processing chamber 702 and a transfer chamber (not shown) is performed through the transfer port 725.

A stage 703 configured to hold the substrate W substantially horizontally is provided in the processing chamber 702. The stage 703 has a substantially circular shape in a plan view, and is supported by a support 731. The surface of the stage 703 is provided with a substantially circular recess 732 in which the substrate W having a diameter of, for example, 300 mm is to be placed. The recess 732 has an inner diameter (e.g., about 1 mm or greater and about 4 mm or less) that is slightly greater than the diameter of the substrate W. The depth of the recess 732 is configured, for example, to be substantially the same as the thickness of the substrate W. The stage 703 is formed of a ceramic material, such as aluminum nitride (AlN) or the like. The stage 703 may be formed of a metal material, such as nickel (Ni) or the like. Instead of the recess 732, a guide ring configured to guide the substrate W may be provided at the periphery of the surface of the stage 703.

A lower electrode 733 is embedded in the stage 703. A temperature adjuster 734 is embedded below the lower electrode 733. The temperature adjuster 734 is configured to adjust the substrate W placed on the stage 703 to a set temperature in accordance with a control signal from a controller 709.

An RF (radio frequency) power supply 735 is connected to the lower electrode 733 through a matcher 735a. The RF power supply 735 is configured to supply, to the lower electrode 733, power having a low frequency (LF) lower than the frequency of an RF power supply 751 described below. The low-frequency power generated by the RF power supply 735 is used as a bias low-frequency power for drawing ions into the substrate W. The frequency of the RF power supply 735 is 450 kHz or greater and 27 MHz or less, and is, for example, 13.56 MHz.

The stage 703 is provided with a plurality of (e.g., three) raising and lowering pins 741 configured to hold and raise/lower the substrate W placed on the stage 703. The material of the raising and lowering pins 741 may be a ceramic, such as alumina (Al₂O₃) or the like, or may be quartz or the like. The lower ends of the raising and lowering pins 741 are attached to a support plate 742. The support plate 742 is connected to a raising and lowering mechanism 744 provided externally of the processing chamber 702 through a raising and lowering shaft 743.

The raising and lowering mechanism 744 is provided, for example, below the gas exhaust chamber 721. A bellows 745 is provided between: an opening 721a for the raising and lowering shaft 743 formed in the lower surface of the gas exhaust chamber 721; and the raising and lowering mechanism 744. The support plate 742 may have such a shape as to rise and descend without interfering with the support 731 of the stage 703. The raising and lowering pins 741 are configured to rise and descend due to the raising and lowering mechanism 744 between the upper space of the surface of the stage 703 and the lower space of the surface of the stage 703. In other words, the raising and lowering pins 741 are configured to project from the upper surface of the stage 703.

The lower end of the support 731 penetrates through an opening 721b of the gas exhaust chamber 721 and is supported by a raising and lowering mechanism 746 through a rising and lowering plate 747 disposed below the processing chamber 702. A bellows 748 is provided between the bottom of the gas exhaust chamber 721 and the rising and lowering plate 747, and the airtightness of the interior of the processing chamber 702 is maintained by an upward and downward movement of the rising and lowering plate 747.

When the raising and lowering mechanism 746 raises and lowers the rising and lowering plate 747, it is possible to raise and lower the stage 703. This can adjust the gap between the stage 703 and the lower surface of an upper electrode plate 705.

A top wall 727 of the processing chamber 702 is provided with the upper electrode plate 705 through an insulating member 728. The upper electrode plate 705 forms an upper electrode, and is disposed to face the lower electrode 733 in parallel to the lower electrode 733. An RF power supply 751 is connected to the upper electrode plate 705 through a matcher 751a. The RF power supply 751 is configured to supply, to the upper electrode plate 705, power having a high frequency (HF) that is higher than the frequency of the RF power supply 735. The high-frequency power generated by the RF power supply 751 is used as high-frequency power for generating a plasma necessary for formation of a film over the substrate W. The frequency of the RF power supply 751 is, for example, 450 KHz or greater and 2.45 GHz or less. By supplying the RF power from the RF power supply 751 to the upper electrode plate 705, an RF electric field is generated between the stage 703 and the upper electrode plate 705. The upper electrode plate 705 includes a hollow gas diffusion chamber 752. The lower surface of the gas diffusion chamber 752 is provided with numerous holes 753 through which the processing gas is dispersed and supplied to the processing chamber 702. The numerous holes 753 are arranged, for example, at equal intervals. A heater 754 is embedded in the upper electrode plate 705, for example, upward of the gas diffusion chamber 752. The heater 754 is heated to a set temperature by supply of power from a power supply (not shown) in accordance with a control signal from the controller 709.

The gas diffusion chamber 752 is provided with a gas supply path 706. The gas supply path 706 communicates with the gas diffusion chamber 752. On the upstream side of the gas supply path 706, a gas source 761 is connected through a gas line 762. The gas source 761 includes, for example, supply sources of various processing gases, a mass flow controller, and a valve (none of which are shown). The processing gases used in a formation method of the carbon-containing film include a carbon-containing gas. The carbon-containing gas contains at least one of a gas containing carbon (C) and hydrogen (H) (CxHy), a gas containing carbon (C) and fluorine (F) (CxFy), a gas containing carbon (C) and oxygen (O) (e.g., CO₂), or a gas containing carbon (C) and a metal (e.g., an organometallic precursor, such as TDMAT or the like). In CxHy and CxFy, x and y are desired numbers. Also, the carbon-containing gas contains, for example, CH₄, C₂H₂, C₂H₄, C₃H₆, or C₆H₆. The processing gas may also contain an inert gas or a dilution gas (e.g., H₂, Ar, He, O₂, or N₂). The processing gas may further contain a hydrogen gas. Various gases are introduced into the gas diffusion chamber 752 from the gas source 761 through the gas line 762.

The plasma processing apparatus 700 includes the controller 709. The controller 709 is, for example, a computer, and includes a central processing unit (CPU), a random access memory (RAM), a read only memory (ROM), an auxiliary storage, and the like. The CPU is driven in accordance with programs stored in the ROM or the auxiliary storage, and controls how the plasma processing apparatus 700 is driven. The controller 709 may be provided internally or externally of the plasma processing apparatus 700. When the controller 709 is provided externally of the plasma processing apparatus 700, the controller 709 can control the plasma processing apparatus 700 by a communication means, such as wired communication, wireless communication, or the like.

With this configuration, the plasma processing apparatus 700 forms a carbon-containing film over the substrate surface. Specifically, the controller 709 forms the carbon-containing film by a plasma of the carbon-containing gas. The controller 709 controls the temperature adjuster 734 to set the temperature of the substrate W to a predetermined temperature. The temperature adjuster 734 controls the pressure adjuster 723 and the gas exhauster 724 to set the internal pressure of the processing chamber 702 to a predetermined pressure. Also, the controller 709 controls the gas source 761 to supply the carbon-containing gas into the processing chamber 702. Further, the controller 709 controls the RF power supply 751 to apply high-frequency power (HF) to the upper electrode plate 705. The controller 709 controls the RF power supply 735 to apply low-frequency power (LF) to the lower electrode 733. This generates the plasma of the carbon-containing gas, and forms the carbon-containing film over the substrate W by the generated plasma.

The following is an example of film formation conditions for forming the carbon-containing film 230 having a film stress of 1 GPa or more.

Processing pressure: 5 mT or higher and 200 mT or lower Plasma power: 10 W or higher and 300 W or lower Thickness of the carbon-containing film: 20 nm or greater and 100 nm or less

The above describes an example in which the high-frequency power (HF) is applied to the upper electrode plate 705 and the low-frequency power (LF) is applied to the lower electrode 733, but this is by no means a limitation. For example, two frequencies of the high-frequency power (HF) and the low-frequency power (LF) may be applied to the upper electrode plate 705, and two frequencies of the high-frequency power (HF) and the low-frequency power (LF) may be applied to the lower electrode 733.

Next, film delamination of the carbon-containing film 230 when Si is contained in the substrate surface will be described.

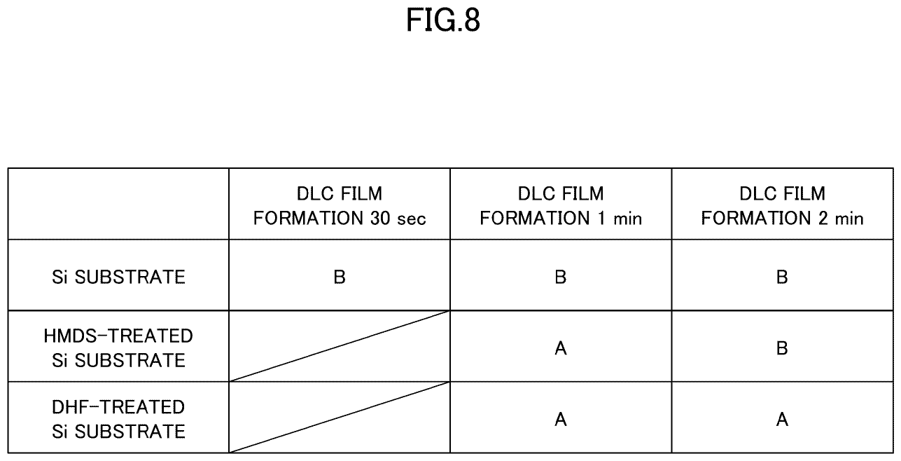

FIG. 8 is a diagram illustrating a state of the carbon-containing film 230 formed over the substrate surface. Here, DLC films were formed over new Si substrates, Si substrates subjected to a hydrophobizing treatment with HMDS (see S103), and Si substrates subjected to a hydrophobizing treatment with DHF (see S103) for film-forming times of 30 sec, 1 min, and 2 min. In FIG. 8, “A” indicates that there was no film delamination, and “B” indicates that there was film delamination.

As illustrated in FIG. 8, in the case of the new Si substrates, the film delamination was confirmed in all of the DLC films formed for the film-forming times of 30 sec, 1 min, and 2 min.

Conversely, in the case of the Si substrates subjected to the hydrophobizing treatment with HMDS (see S103), no film delamination occurred in the DLC film formed for the film-forming time of 1 min. The film stress of this DLC film was −2.1 GPa, and the film thickness of this DLC film was 128 nm. In the case of the Si substrates subjected to the hydrophobizing treatment with HMDS (see S103), the film delamination was confirmed in the DLC film formed for the film-forming time of 2 min. By performing the pre-treatment (see S102) before the hydrophobizing treatment (see S103), it is possible to achieve a state in which Si—OH is abundant. By performing the hydrophobizing treatment (see S103) after the pre-treatment (see S102), it is possible to increase the amount of HMDS that is to be physically adsorbed onto and/or chemically bonded to the substrate surface. Thus, film delamination can be further suppressed.

In the case of the Si substrates subjected to the hydrophobizing treatment with DHF (see S103), no film delamination occurred in the DLC film formed for the film-forming time of 1 min. The film stress of this DLC film was −2.1 GPa, and the film thickness of this DLC film was 130 nm. Also, in the Si substrates subjected to the hydrophobizing treatment with DHF (see S103), no film delamination occurred in the DLC film formed for the film-forming time of 2 min. The film stress of this DLC film was −2.9 GPa, and the film thickness of this DLC film was 148 nm. By performing the pre-treatment (see S102) before the hydrophobizing treatment (see S103), it is possible to achieve a state in which Si—OH is abundant. By performing the hydrophobizing treatment (see S103) after the pre-treatment (see S102), it is possible to increase the amount of HMDS that is to be physically adsorbed onto and/or chemically bonded to the substrate surface. Thus, film delamination can be further suppressed.

Next, film delamination of the carbon-containing film 230 in the case in which Si is contained in the substrate surface and in the case in which the substrate surface is TiN will be described.

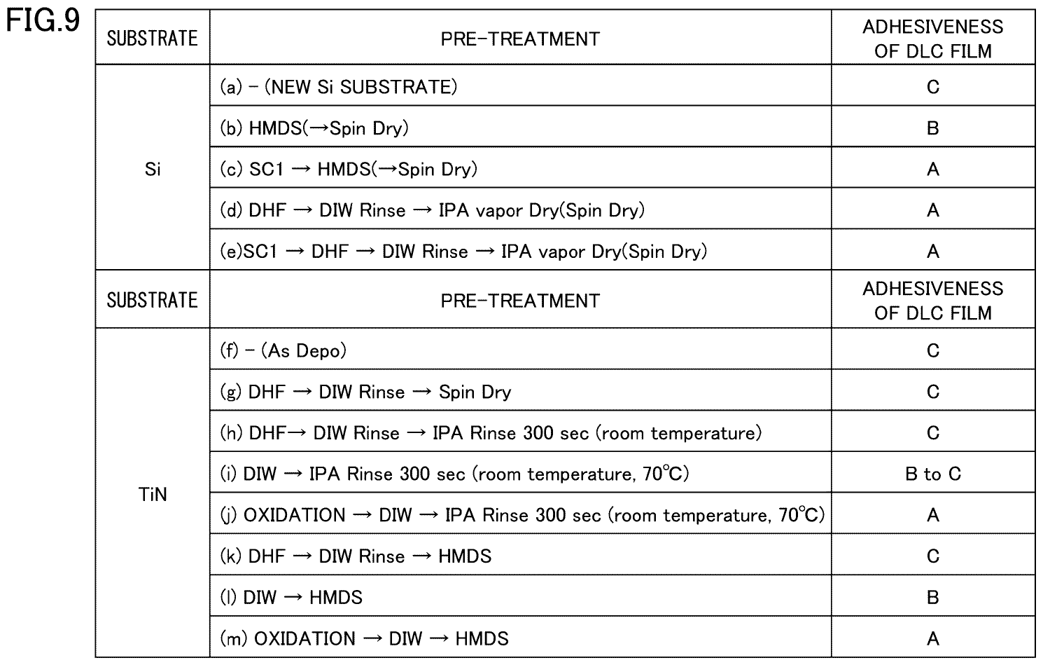

FIG. 9 is a diagram illustrating a relationship between various pre-treatments and adhesiveness of a DLC film. Note that “C” indicates that film delamination occurred. “B” indicates that film delamination is likely to occur due to change over time and/or that film delamination is likely to occur due to high compressive stress. “A” indicates that no film delamination occurred. In (a) to (e), the substrate surface is Si, and in (f) to (m), the substrate surface is a TiN film formed through PVD.

In (a), a DLC film was formed over the substrate surface of a new Si substrate in the plasma processing apparatus 700. In this case, Si—O₂ and Si—OH are assumed to coexist at the substrate surface before the formation of the DLC film.

In (b), in the cleaning apparatus 400, the substrate surface of the Si substrate was treated with HMDS, and drying (Spin Dry) of the substrate W was performed by rotating the stage 420. Subsequently, a DLC film was formed over the substrate surface in the plasma processing apparatus 700. In this case, Si—O₂ or Si—O— (CH₃)₃ is assumed to be formed at the substrate surface before the formation of the DLC film.

In (c), the substrate surface of the Si substrate was pre-treated with an ammonia-hydrogen peroxide mixture (SC1) in the cleaning apparatus 400. The pre-treatment with the ammonia-hydrogen peroxide mixture corresponds to the pre-treatment step of step S102 illustrated in FIG. 1. Next, the substrate surface was treated with HMDS in the cleaning apparatus 400. The treatment with HMDS corresponds to the hydrophobization step of step S103 illustrated in FIG. 1. Then, drying (Spin Dry) of the substrate W was performed by rotating the stage 420. Subsequently, a DLC film was formed over the substrate surface in the plasma processing apparatus 700. In this case, Si—O— (CH₃)₃ is assumed to be formed at the substrate surface before the formation of the DLC film.

In (d), the substrate surface of the Si substrate was treated with DHF in the cleaning apparatus 400. This treatment with DHF corresponds to the hydrophobization step of step S103 illustrated in FIG. 1. Next, in the cleaning apparatus 400, removal (DIW Rinse) of the chemical solution was performed through washing with pure water, and drying (IPA vapor Dry (Spin Dry)) of the substrate W was performed by rotating the stage 420 in an IPA atmosphere. Subsequently, a DLC film was formed over the substrate surface in the plasma processing apparatus 700. In this case, it is assumed that the substrate surface before the formation of the DLC film is Si—H, but there are portions in which Si—O₂ remains and Si—H cannot be formed due to remaining particles and organic substances.

In (e), the substrate surface of the Si substrate was pre-treated with an ammonia-hydrogen peroxide mixture (SC1) in the cleaning apparatus 400. The pre-treatment with the ammonia-hydrogen peroxide mixture corresponds to the pre-treatment step of step S102 illustrated in FIG. 1. Next, the substrate surface was treated with DHF in the cleaning apparatus 400. The treatment with DHF corresponds to the hydrophobization step of step S103 illustrated in FIG. 1. Next, in the cleaning apparatus 400, removal (DIW Rinse) of the chemical solution was performed through washing with pure water, and drying (IPA vapor Dry (Spin Dry)) of the substrate W was performed by rotating the stage 420 in an IPA atmosphere. Subsequently, a DLC film was formed over the substrate surface in the plasma processing apparatus 700. In this case, the substrate surface before the formation of the DLC film is assumed to be completely Si—H due to removal of particles and organic substances. Si—H is formed at the substrate surface that is cleaner than the substrate surface obtained in (d). Thus, it is considered that film delamination of a DLC film having a high film stress is more suppressed.

In (a) to (e), a DLC film having a film stress of −3 GPa and a film thickness of 150 nm was formed. As illustrated in FIG. 9, it was confirmed in (c), (d), and (e) that film delamination of the DLC film could be suppressed and adhesiveness of the DLC film could be improved.

In (f), a DLC film was formed over the substrate surface of a TiN film formed through PVD in the plasma processing apparatus 700. In this case, the substrate surface before the formation of the DLC film is assumed to be TiN, or to be TiO₂ due to oxidation in an open-air atmosphere.

In (g), in the cleaning apparatus 400, a TiN film formed through PVD was treated with DHF, removal (DIW Rinse) of the chemical solution was performed through washing with pure water, and drying (Spin Dry) of the substrate W was performed by rotating the stage 420. Subsequently, a DLC film was formed over the substrate surface in the plasma processing apparatus 700. In this case, the substrate surface before the formation of the DLC film is assumed to be TiN.

In (h), in the cleaning apparatus 400, a TiN film formed through PVD was treated with DHF, removal (DIW Rinse) of the chemical solution was performed through washing with pure water, and IPA cleaning (IPA Rinse) was performed at room temperature for 300 seconds. Subsequently, a DLC film was formed over the substrate surface in the plasma processing apparatus 700. In this case, the substrate surface before the formation of the DLC film is assumed to be TiN.

In (i), in the cleaning apparatus 400, a TiN film formed through PVD was treated with pure water (DIW), thereby changing TiO₂ to TiOH (some remain unchanged, i.e., TiN), followed by IPA cleaning (IPA Rinse) at room temperature or 70° C. for 300 seconds. Subsequently, a DLC film was formed over the substrate surface in the plasma processing apparatus 700. In this case, O—CH₃ is assumed to be physically adsorbed onto or chemically bonded to Ti—OH at the substrate surface before the formation of the DLC film.

In (j), a TiN film formed through PVD was oxidized. This oxidizing treatment changes the substrate surface from a state in which TiN and TiO₂ coexist to a state in which TiO₂ is abundant. Next, the oxidized substrate was treated with pure water (DIW) in the cleaning apparatus 400. The treatment with pure water changes TiO₂ at the substrate surface to TiOH. The oxidizing treatment and the treatment with pure water correspond to the pre-treatment step of step S102 illustrated in FIG. 1.

Next, IPA cleaning (IPA rinse) of the substrate was performed at room temperature or 70° C. for 300 seconds in the cleaning apparatus 400. By exposing the substrate W to IPA serving as the second surface treatment agent, O—CH₃ is physically adsorbed onto Ti—OH at the substrate surface. The IPA cleaning corresponds to the hydrophobization step of step S103 illustrated in FIG. 1. Subsequently, a DLC film was formed over the substrate surface in the plasma processing apparatus 700. In this case, O⇒CH₃ is assumed to be physically adsorbed onto or chemically bonded to Ti—OH at the substrate surface before the formation of the DLC film.

In (k), in the cleaning apparatus 400, a TiN film formed through PVD was treated with DHF, and removal (DIW Rinse) of the chemical solution was performed through washing with pure water, followed by treating with HMDS. Subsequently, a DLC film was formed over the substrate surface in the plasma processing apparatus 700. In this case, HMDS is assumed to be physically adsorbed onto TiN at the substrate surface before the formation of the DLC film.

In (l), in the cleaning apparatus 400, a TiN film formed through PVD was treated with pure water (DIW), thereby changing TiO₂ to TiOH (some remain unchanged, i.e., TiN), followed by treating with HMDS. Subsequently, a DLC film was formed over the substrate surface in the plasma processing apparatus 700. In this case, HMDS is assumed to be physically adsorbed onto or chemically bonded to TiOH at the substrate surface before the formation of the DLC film.

In (m), a TiN film formed through PVD was oxidized. This oxidizing treatment changes the substrate surface from a state in which TiN and TiO₂ coexist to a state in which TiO₂ is abundant. Next, the oxidized substrate was treated with pure water (DIW) in the cleaning apparatus 400. The treatment with pure water changes TiO₂ at the substrate surface to TiOH. The oxidizing treatment and the treatment with pure water correspond to the pre-treatment step of step S102 illustrated in FIG. 1.

Next, the substrate was treated with HMDS in the cleaning apparatus 400. By exposing the substrate W to HMDS serving as the second surface treatment agent, HMDS is physically adsorbed onto or chemically bonded to Ti—OH at the substrate surface. The treatment with HMDS corresponds to the hydrophobization step of step S103 illustrated in FIG. 1. Subsequently, a DLC film was formed over the substrate surface in the plasma processing apparatus 700. In this case, HMDS is assumed to be physically adsorbed onto or chemically bonded to TiOH at the substrate surface before the formation of the DLC film.

In (f) to (m), a DLC film having a film stress of −3 GPa, a density of 2.1 g/cm³, and a film thickness of 40 nm was formed. As illustrated in FIG. 9, it was confirmed in (j) and (m) that film delamination of the DLC film could be suppressed and adhesiveness of the DLC film could be improved.

As described above, before the formation of the carbon-containing film over the substrate surface, a hydrophilic surface is formed by exposing the substrate surface to the first surface treatment agent to perform the pre-treatment step (see S102) for increasing the number of OH groups at the substrate surface. Subsequently, a hydrophobic surface is formed by exposing the substrate surface to the second surface treatment agent to cause the second surface treatment agent to be physically adsorbed onto and/or chemically bonded to the OH groups at the substrate surface, or cause the second surface treatment agent to be chemically reacted with the OH groups at the substrate surface. Then, by forming a DLC film over the hydrophobic surface, it is possible to improve adhesiveness of the DLC film. Also, it is possible to suppress film delamination of the DLC film.

Also, as the film density of a DLC film becomes higher, the compressive stress of the DLC film tends to be higher. According to the substrate processing method illustrated in FIG. 1, film delamination can be suppressed in a DLC film having a high film density and a high compressive stress of 1 GPa or more.

According to one aspect, the present disclosure can provide a substrate processing method in which film delamination is suppressed.

Although the substrate processing method for forming the DLC film at the substrate surface has been described above, the present disclosure is not limited to the above embodiments and the like. Various modifications and improvements are possible within the scope of the intent of the present disclosure recited in claims.

What is claimed is:

1. A substrate treatment method, comprising:
a) exposing a substrate to a first surface treatment agent, thereby pre-treating a substrate surface of the substrate;
b) exposing the substrate treated in a) to a second surface treatment agent, thereby hydrophobizing the substrate surface; and
c) exposing the substrate treated in b) to a plasma of a processing gas containing a carbon-containing gas, thereby forming a carbon-containing film having a film stress of 1 GPa or more over the hydrophobized substrate surface.

2. The substrate treatment method according to claim 1, wherein
the substrate surface contains Si, and
the first surface treatment agent contains at least one of an ammonia-hydrogen peroxide mixture, H₂O₂, a hydrochloric acid-hydrogen peroxide mixture, ozone (O₃) water, a sulfuric acid-hydrogen peroxide mixture, or an ammonium peroxodisulfate aqueous solution.

3. The substrate treatment method according to claim 2, wherein
the first surface treatment agent contains ammonia, hydrogen peroxide, and pure water, and
a ratio of the ammonia, the hydrogen peroxide, and the pure water is greater than or equal to 1:1:20 and less than or equal to 1:1:100.

4. The substrate treatment method according to claim 3, wherein
a treatment temperature in a) is 40° C. or higher and 60° C. or lower.

5. The substrate treatment method according to claim 1, wherein
the substrate surface is TiN, and
a) includes
oxidizing the substrate surface, and
exposing the substrate to pure water serving as the first surface treatment agent, thereby treating the substrate surface.

6. The substrate treatment method according to claim 1, wherein
a) forms, at the substrate surface, a functional group that is to be physically adsorbed onto the second surface treatment agent, a functional group that is to be chemically bonded to the second surface treatment agent, a functional group that is to be physically adsorbed onto and chemically bonded to the second surface treatment agent, or a functional group that is to be chemically reacted with the second surface treatment agent.

7. The substrate treatment method according to claim 6, wherein
a) forms an OH group at the substrate surface.

8. The substrate treatment method according to claim 1, wherein
the second surface treatment agent contains at least one of DHF, HMDS, IPA, TMSDMA, a silane coupling agent, or cetyl alcohol.

9. The substrate treatment method according to claim 8, wherein
the second surface treatment agent contains HF and pure water, and
a ratio of the HF and the pure water is greater than or equal to 1:50 and less than or equal to 1:200.

10. The substrate treatment method according to claim 9, wherein
a treatment temperature in b) is 60° C. or higher and 150° C. or lower.

11. The substrate treatment method according to claim 1, wherein
the carbon-containing gas contains at least one of a gas containing carbon (C) and hydrogen (H), a gas containing carbon (C) and fluorine (F), a gas containing carbon (C) and oxygen (O), or a gas containing carbon (C) and a metal.

12. The substrate treatment method according to claim 11, wherein
the processing gas contains an inert gas.

13. The substrate treatment method according to claim 12, wherein
the processing gas further contains a hydrogen gas.

14. The substrate treatment method according to claim 11, wherein
a processing pressure in c) is 5 mT or higher and 200 mT or lower.

15. The substrate treatment method according to claim 11, wherein
plasma power in c) is 10 W or higher and 300 W or lower.

16. The substrate treatment method according to claim 11, wherein
a film thickness of the carbon-containing film is 20 nm or greater and 100 nm or less.

17. The substrate treatment method according to claim 1, wherein
the substrate surface is Si, SiN, or TiN.

18. The substrate treatment method according to claim 1, wherein
the substrate surface is TiN, and
the substrate treatment method further includes forming a TiN film before a).

19. The substrate treatment method according to claim 18, wherein
a film thickness of the TiN film is 20 nm or greater and 100 nm or less.
